(19) United States
(12) Patent Application Publication
(10) Pub. No.: US 2018/0019747 A1
(43) Pub. Date: Jan. 18, 2018

(54) SIGNAL TRANSMISSION CIRCUIT AND DRIVING DEVICE FOR SWITCHING ELEMENT

(71) Applicant: DENSO CORPORATION, Kariya-city, Aichi-pref. (JP)

(72) Inventors: Kohei IKEGAWA, Kariya-city (JP); Shuntaro OKADA, Kariya-city (JP)

(21) Appl. No.: 15/548,446

(22) PCT Filed: Mar. 25, 2016
(86) PCT No.: PCT/JP2016/001754

§ 371 Date: Aug. 3, 2017

(30) Foreign Application Priority Data
Apr. 15, 2015 (JP) 2015-83318

(51) Int. Cl. H03K 17/16; H02M 1/08; H03K 21/10; H02P 27/06

(52) U.S. Cl. CPC H03K 17/168; H02M 1/08; H03K 21/10; H02P 27/06

(57) ABSTRACT

A signal transmission circuit includes: a transformer; a primary side circuit that: generates a pulse signal, for flowing a current in a primary side coil of the transformer in one direction during a period in which an input signal changing at a binary level indicates a first level, in a cycle shorter than a change cycle of the input signal; and generates another pulse signal, for flowing a current in the primary side coil in another direction opposite to the one direction during a period in which the input signal indicates a second level, in another cycle shorter than the change cycle of the input signal; and a secondary side circuit that: distinguishes the first level and the second level according to a voltage having a different polarity which is generated in a secondary side coil of the transformer; and reproduces the input signal.

### CROSS REFERENCE TO RELATED APPLICATION

This application is a U.S. national stage application of International Patent Application No. PCT/JP2016/001754 filed on Mar. 25, 2016 and is based on Japanese Patent Application No. 2015-83318 filed on Apr. 15, 2015, the disclosure of which is incorporated herein by reference.

### TECHNICAL FIELD

The present disclosure relates to a signal transmission circuit for transmitting a signal input to a primary side of a transformer to a secondary side and a driving device for a switching element including the signal transmission circuit.

### BACKGROUND ART

For example, in a drive circuit such as an inverter circuit for driving a motor, since a drive signal is transmitted in a state of being insulated from a switching element, a signal transmission circuit having an on-chip transformer, small in size, and short in delay time may be used (for example, refer to Patent Literatures 1 and 2). In order to prevent an overcurrent from flowing in the drive circuit described above due to a short circuit of upper and lower arms to destroy the switching elements and the like, the driving circuit is required not to malfunction even when noise is applied to the driving circuit.

In the configuration disclosed in Patent Literature 1, noise tolerance is ensured, but since a feedback transformer is necessary, a circuit scale becomes large. Further, in Patent Literature 2, a configuration capable of reducing the generation of a noise voltage caused by a common mode voltage is realized by a relatively small scale circuit. However, when noise is applied to the circuit during steady operation, there is a possibility that a level of the transmitted signal is reversed, and noise tolerance is insufficient.

### PATENT LITERATURE

Patent Literature 1: JP-2011-055611-A

Patent Literature 2: JP-2011-092864-A

### SUMMARY

It is an object of the present disclosure to provide a signal transmission circuit capable of transmitting an input signal in an insulated state with a small circuit scale while securing noise tolerance, and a driving device for a switching element including the signal transmission circuit.

According to a first aspect of the present disclosure, a signal transmission circuit includes: a transformer; a primary side circuit that: generates a pulse signal, for flowing a current in a primary side coil of the transformer in one direction during a period in which an input signal changing at a binary level indicates a first level, in a cycle shorter than a change cycle of the input signal; and generates another pulse signal, for flowing a current in the primary side coil in another direction opposite to the one direction during a period in which the input signal indicates a second level, in another cycle shorter than the change cycle of the input signal; and a secondary side circuit that: distinguishes the first level and the second level according to a voltage having a different polarity which is generated in a secondary side coil of the transformer; and reproduces the input signal.

According to the signal transmission circuit described above, even when the level is inverted due to an influence of noise during a period when the input signal is indicative of the first or second level, a current based on the pulse signal having the cycle shorter than that generated by the primary side circuit according to the first or second level repetitively flows in the secondary side coil of the transformer, and a voltage having a polarity corresponding to the current is generated.

Since the secondary side circuit reproduces the input signal according to the polarity of the voltage, the inverted level is restored to the original first or second level within a short time. Accordingly, while an electric insulation between the primary side and the secondary side is performed with the use of the transformer, the influence caused by the level inversion due to the noise is reduced, and a control using the input signal can be restored to the original state more quickly.

According to a second aspect of the present disclosure, a signal transmission circuit includes: a transformer; a primary side circuit that: generates a pulse signal, for flowing a current in a primary side coil of the transformer in one direction when an input signal changing at a binary level indicates a first level, in a cycle shorter than a change cycle of the input signal; and generates another pulse signal, for flowing a current in the primary side coil in another direction opposite to the one direction during a period in which the input signal indicates a second level, in another cycle shorter than the change cycle of the input signal; and a secondary side circuit that: distinguishes the first level and the second level according to a voltage having a different polarity which is generated in a secondary side coil of the transformer; and reproduces the input signal.

In the signal transmission circuit described above, the input signal can be transmitted in an insulated state with a small circuit scale while securing noise tolerance.

According to a third aspect of the present disclosure, a drive device of a switching element includes: the signal transmission circuit according to the first or second aspect. The driving device controls a drive of the switching element according to an input signal regenerated by the secondary side circuit of the signal transmission circuit.

In the drive device of the switching element described above, the input signal can be transmitted in an insulated state with a small circuit scale while securing noise tolerance.

### BRIEF DESCRIPTION OF DRAWINGS

The above and other objects, features and advantages of the present disclosure will become more apparent from the following detailed description made with reference to the accompanying drawings. In the drawings:

FIG. 1 is a diagram illustrating an electric configuration of a signal transmission circuit according to a first embodiment;

FIG. 2 is a diagram schematically illustrating a configuration of a motor drive circuit including the signal transmission circuit;

FIG. 3 is a timing chart illustrating the operation of the signal transmission circuit in detail;

FIG. 4 is a timing chart schematically illustrating the operation of the signal transmission circuit;

FIG. 5 is a diagram illustrating an electric configuration of a signal transmission circuit in a conventional art;

FIG. 6 is a diagram illustrating a simulation result of each waveform showing the operation of the conventional art;

FIG. 7 is a diagram illustrating a simulation result of each signal waveform in the case where a pulse period output in a period in which an input signal DIN is indicative of a high level is 0.5 μsec according to the first embodiment;

FIG. 8 is a diagram illustrating a simulation result of each signal waveform in the case where the pulse period is set to 1.0 μsec according to the first embodiment;

FIG. 9 is a diagram illustrating a simulation result of each signal waveform in the case where the pulse period is set to 2.0 μsec;

FIG. 10 is a diagram comparing a current consumption between the conventional art and the cases illustrated in FIG. 7 to FIG. 9;

FIG. 11 is a diagram illustrating an electric configuration of a signal transmission circuit according to a second embodiment; and

FIG. 12 is a timing chart illustrating the operation of the signal transmission circuit in detail.

### DETAILED DESCRIPTION

### First Embodiment

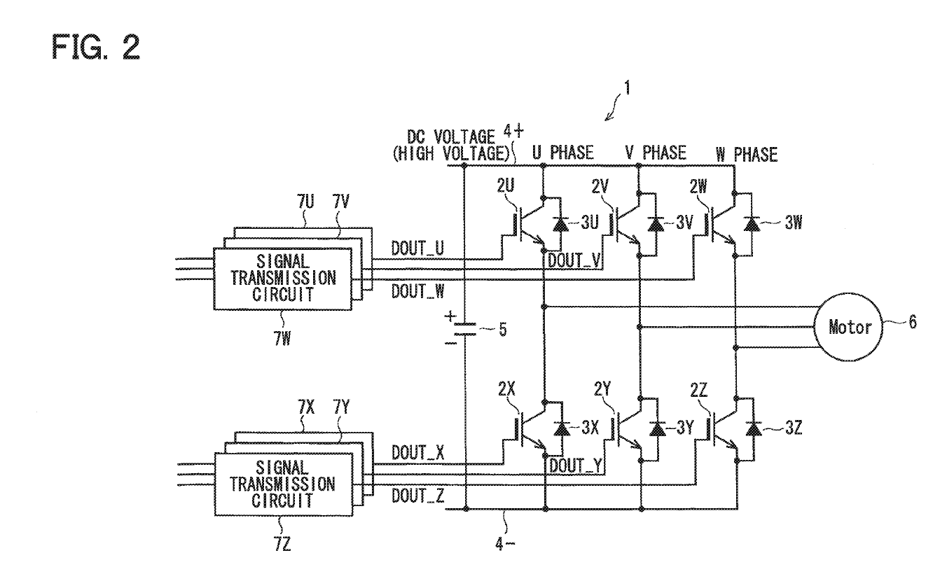

As illustrated in FIG. 2, an inverter circuit 1 is configured by connecting six IGBTs 2U, 2V, 2W, 2X, 2Y, and 2Z (switching elements) in a three-phase bridge configuration. Free-wheel diodes 3 (U to Z) are connected between a collector and an emitter of each IGBT 2 (U to Z). A smoothing capacitor 5 is connected between DC buses 4+ and 4− of the inverter circuit 1, and a DC voltage supplied from a DC power supply not shown is applied to the smoothing capacitor 5. Each phase output terminal of the inverter circuit 1 is connected to each phase stator coil (not shown) of a three-phase motor 6. Gate signals DOUT (U to Z) are input to gates of the IGBTs 2 (U to Z) through signal transmission circuits 7 (U to Z), respectively.

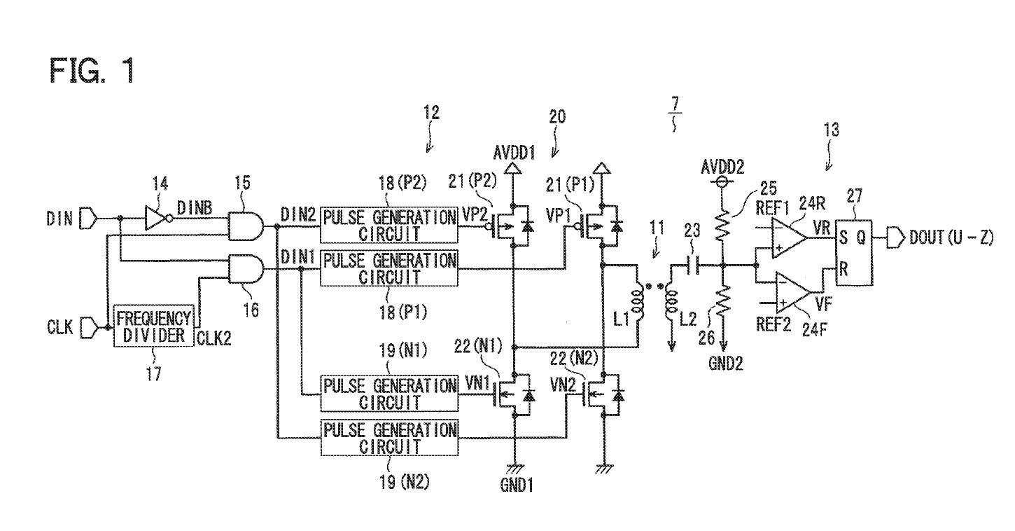

As illustrated in FIG. 1, each of the signal transmission circuits 7 (drive devices) includes a transformer 11, a primary side circuit 12 that is connected to a primary side coil L 1 of the transformer 11, and a secondary side circuit 13 that is connected to a secondary side coil L2. In the primary side circuit 12, an input signal DIN is input to one input terminal of an AND gate 15 (second logic circuit) through a NOT gate 14 (second logic circuit), and also input directly to one input terminal of another AND gate 16 (first logic circuit). The input signal DIN is a signal that changes to a binary level of high and low at a predetermined frequency, and if the high level is set to a “first level”, the low level is a “second level”.

A clock signal CLK (first clock signal) supplied from an oscillation circuit not shown is input to the other input terminal of the AND gate 15 and is also input to the other input terminal of the AND gate 16 through a frequency divider 17. Incidentally, a frequency of the clock signal CLK is set to be sufficiently higher than a frequency (for example, on the order of kHz) of the input signal DIN (for example, on the order of MHz).

An output terminal of the AND gate 15 is connected to respective input terminals of pulse generation circuits 18 (P2) and 19 (N2) (second on signal output circuits), and an output terminal of the AND gate 16 is connected to respective input terminals of pulse generation circuit 18 (P1) and 19 (N1) (first on signal output circuits). The pulse generation circuit 18 outputs a low level pulse as one shot with a rising edge (change edge) of an input signal as a trigger. In addition, the pulse generation circuit 19 similarly outputs a high level pulse as one shot with the rising edge of the input signal as the trigger. A low level pulse width of the former is set to be narrower than the latter high level pulse width.

An H bridge circuit 20 includes p-channel MOSFETs 21(P1) and 21(P2) (switching elements) and n-channel MOSFETs 22(N1) and 22(N2) (switching elements). A parasitic diode is connected between a drain and a source of each of those FETs 21 and 22. A series circuit of the FETs 21(P1) and 22(N2) and a series circuit of the FETs 21(P2) and 22(N1) are connected between a power supply AVDD1 and a ground GND1. Common connection points of those series circuits, that is, respective output terminals of the H bridge circuit 20 are connected to both ends of the primary side coil L1 of the transformer 11.

The secondary side coil L2 of the transformer 11 is in phase with the primary side coil L1. One end of the secondary side coil L2 is connected to a ground GND2 and the other end of the secondary side coil L2 is connected to a non-inverting input terminal of a comparator 24R (set signal generation circuit) and an inverting input terminal of a comparator 24F (reset signal generation circuit) through a capacitor 23. A series circuit of resistor elements 25 and 26 is connected between a power supply AVDD2 and a ground GND2, and a common connection point of the resistor elements 25 and 26 is connected to the input terminals of comparators 24R and 24F.

A reference voltage REF1 is applied to an inverting input terminal of the comparator 24R, and a reference voltage REF2 is applied to a non-inverting input terminal of the comparator 24F. Output terminals of the comparators 24R and 24F are connected to a set terminal S and a reset terminal R of an RS flip-flop 27, respectively. The gate signal DOUT is output from an output terminal Q of the RS flip-flop 27.

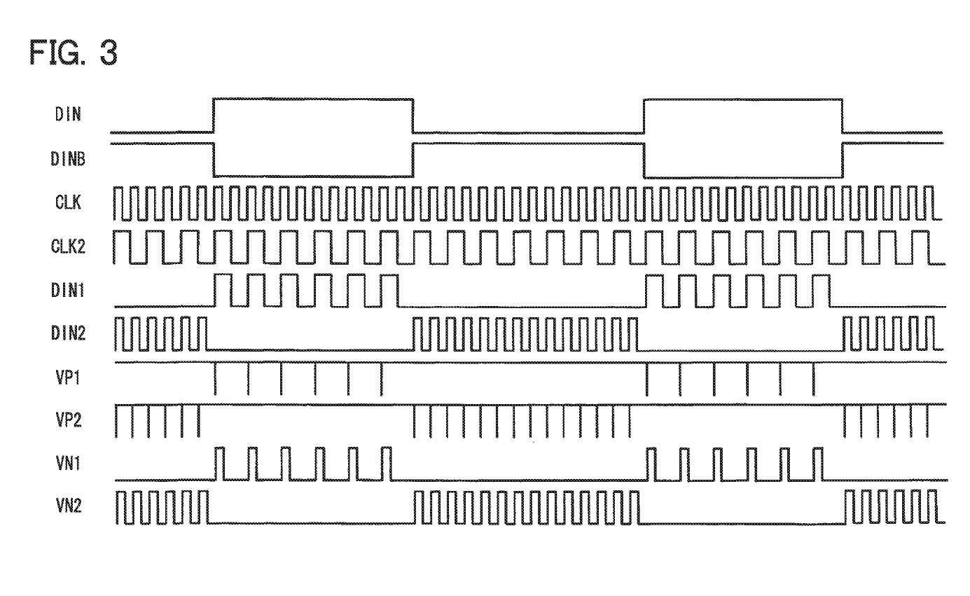

Hereinafter, an operation in the present embodiment will be described. As illustrated in FIG. 3, a clock signal CLK 2 (second clock signal) output through the frequency divider 17 is divided by two. The AND gate 16 outputs a clock signal CLK2 as a signal DIN1 during a period when the input signal DIN is indicative of the high level (gate control). On the other hand, the AND gate 15 outputs the clock signal CLK as a signal DIN2 during a period when the input signal DIN is indicative of the low level.

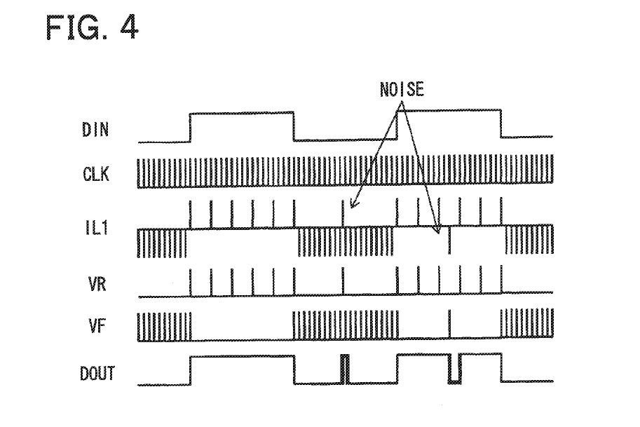

The pulse generation circuits 18(P1) and 19(N1) output a low level pulse VP1 and a high level pulse VN1 (first on signal) with a rising edge of the signal DIN1 as a trigger during a period when the input signal DIN is indicative of the high level, respectively. Since those pulses are gate signals of the FETs 21(P1) and 22(N1), the primary side coil L1 of the transformer 11 is supplied with a current in one direction, for example a positive polarity, in a period during which both of the FETs 21(P1) and 22(N1) are on at the same time. Accordingly, a current of the same phase is induced in the secondary side coil L2, and when a potential of the non-inverting input terminal of the comparator 24R exceeds the reference voltage REF1, the comparator 24R outputs a pulse-like set signal VR with a cycle of the clock signal CLK2 multiple times (refer to FIG. 4). As a result, the RF flip-flop 27 is intermittently and continuously put into a set state, during which the output signal DOUT continues to indicate the high level.

On the other hand, the pulse generation circuits 18(P2) and 19(N2) output a low level pulse VP2 and a high level pulse VN2 (second on signal) with a rising edge of the signal DIN2 as a trigger during a period when the input signal DIN is indicative of the low level, respectively. Since those pulses are gate signals of the FETs 21(P2) and 22(N2), the primary side coil L1 of the transformer 11 is supplied with a current in a reverse direction, in other words, a negative polarity, in a period during which both of the FETs 21(P1) and 22(N1) are on at the same time. Accordingly, a current of the same phase is induced in the secondary side coil L2, and when a potential of the inverting input terminal of the comparator 24F falls below the reference voltage REF2, the comparator 24F outputs a pulse-like reset signal VF with a cycle of the clock signal CLK1 multiple times (refer to FIG. 4). As a result, the RF flip-flop 27 is intermittently and continuously put into a reset state, during which the output signal DOUT continues to indicate the low level.

As a result of the circuit operation described above, the output signal DOUT is in phase with the input signal DIN as illustrated in FIG. 4. Also, in the figure, a current Ill flowing through the primary side coil L1 is indicated by positive and negative bipolar pulses according to a flowing direction.

In this example, as illustrated in the figure, it is assumed that a noise pulse having a polarity opposite to that of the current Ill is applied. When positive noise is applied when the current Ill is negative, the set signal VR is output within a period when the reset signal VF is continuously output to set the RS flip-flop 27, and the output signal DOUT is inverted from the low level and indicates the high level. However, since the reset signal VF is continuously output, the RS flip-flop 27 is reset immediately after that time. Therefore, the output signal DOUT returns to the low level immediately.

Also, when negative noise is applied when the current Ill is positive, the reset signal VF is output within a period when the set signal VR is continuously output to set the RS flip-flop 27, and the output signal DOUT is inverted from the high level and indicates the low level. Also, in this case, since the set signal VR is continuously output, the RS flip-flop 27 is set immediately after that time, and the output signal DOUT returns to the high level immediately.

In this case, the IGBT 2 turns on when the signal supplied to the gate is at the high level, and turns off when the signal supplied to the gate is at the low level. For that reason, it can be evaluated that it is safer to avoid an event of turning on the IGBT2 by the application of noise in a state where the output signal DOUT is indicative of the low level and the IGBT2 is off rather than an event of turning off the IGBT2 by the application of noise in a state where the output signal DOUT is indicative of the high level and the IGBT2 is on.

Therefore, in the present embodiment, the reset signal VF is repetitively output in the cycle shorter than that of the set signal VR, as a result of which even if the RS flip-flop 27 is set by the influence of noise, the RS flip flop 27 is restored in the reset state more quickly. In addition, the cycle on the set signal VR side which is low in urgency of handling is set to be longer, to thereby obtain the effect of reducing the power consumption of the signal transmission circuit 7.

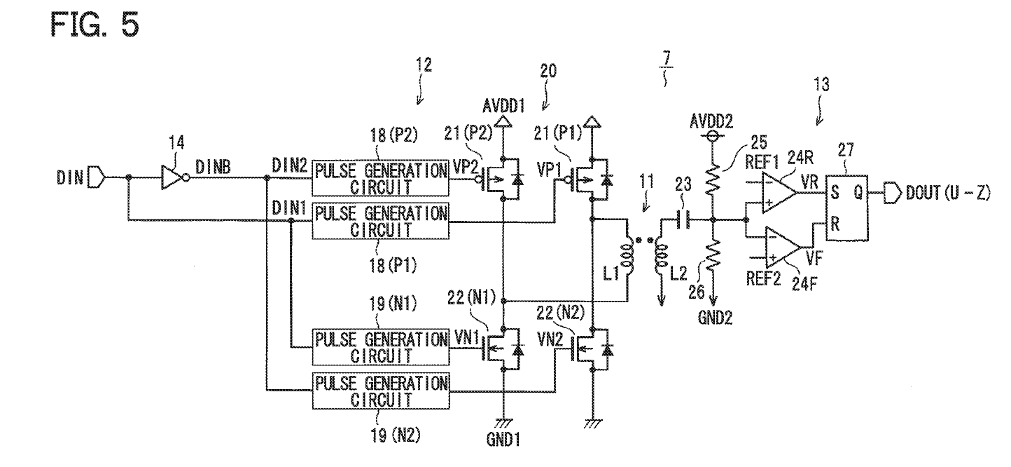

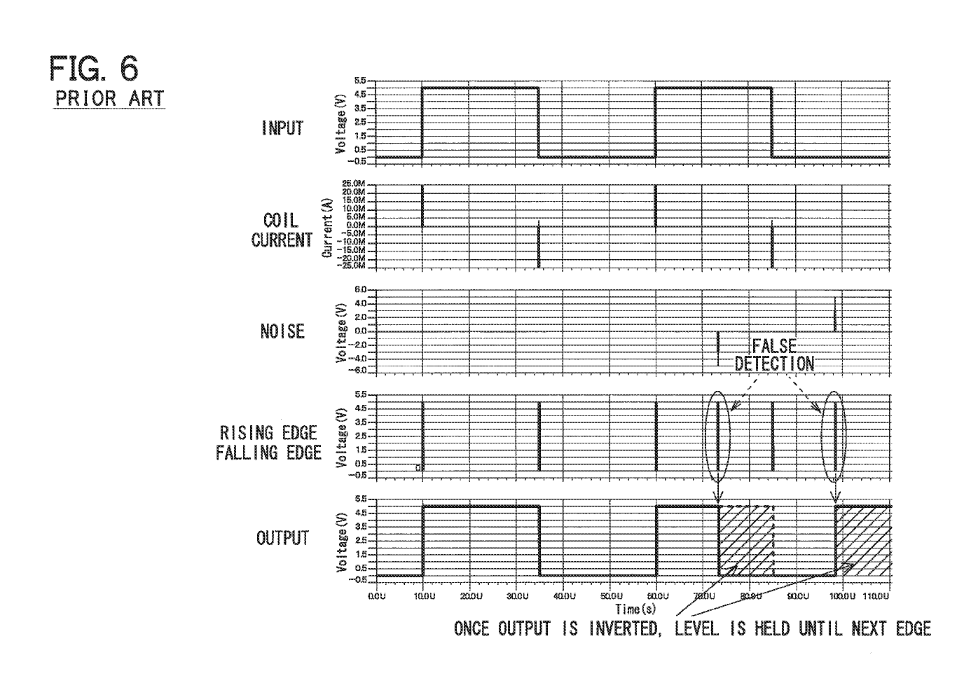

FIG. 5 illustrates the configuration disclosed in Patent Literature 2 at a level corresponding to FIG. 1 of the present embodiment, in which the AND gates 15 and 16, and the frequency divider 17 are deleted from the configuration of the present embodiment without the use of the clock signal CLK. According to the above configuration, as illustrated in FIG. 6, once noise of the opposite polarity is applied, the output signal DOUT maintains the inverted level until a next change edge of a formal signal is input. Therefore, for example, in a state in which the IGBT 2U on an upper arm side is off and the IGBT 2X on a lower arm side is on, when the IGBT 2U on the upper arm side is turned on due to the influence of noise, short-circuit current continues to flow during that situation. If the state in which the short-circuit current flows continues as it is, the IGBTs 2U and 2X may be destroyed.

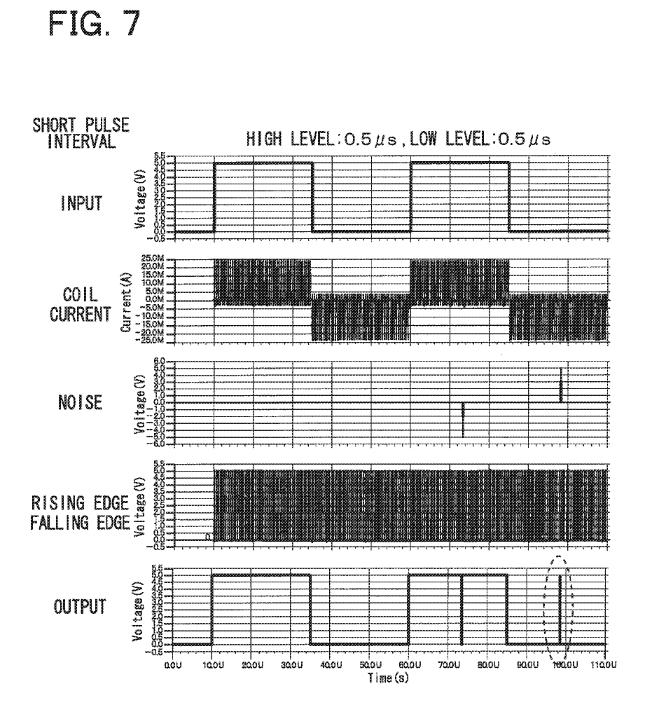

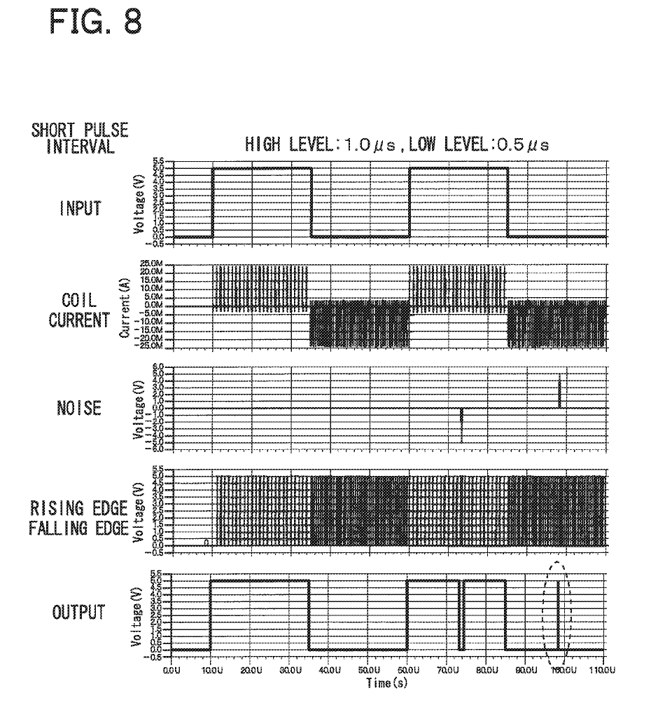

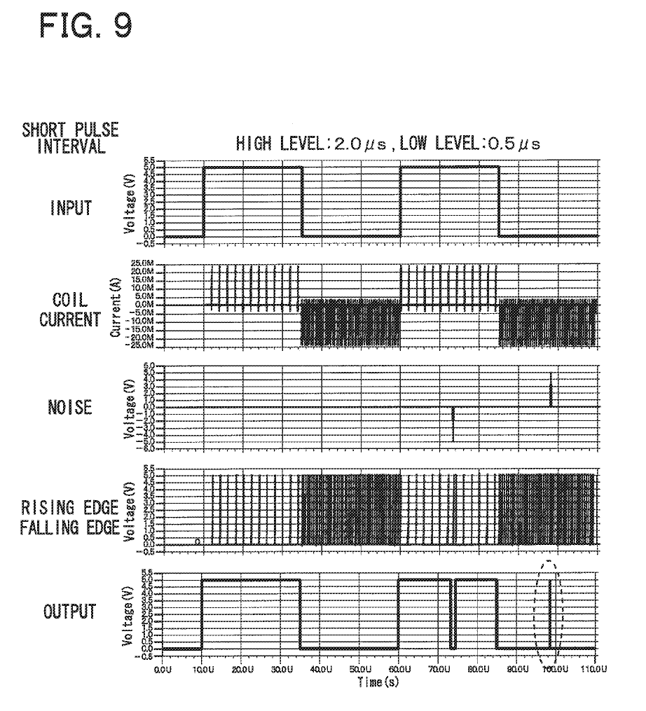

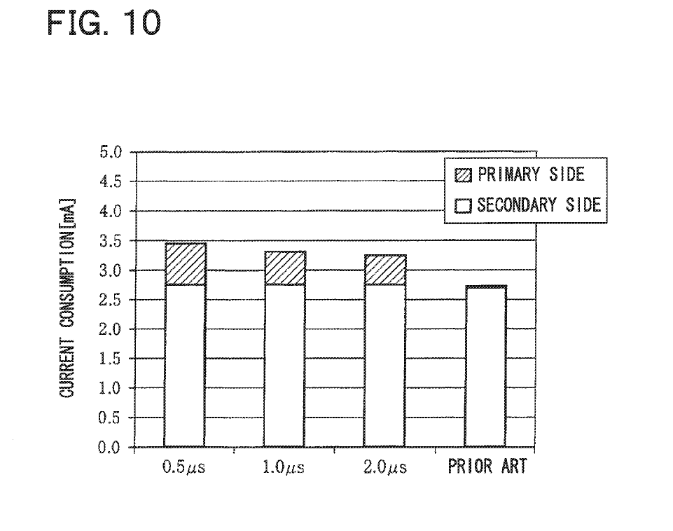

FIGS. 7 to 9 illustrate the simulation of the respective signal waveforms in the cases where the pulse period output during the period when the input signal DIN is indicative of the low level is fixed to 0.5 μsec and the pulse period output during the period when the input signal DIN is indicative of the high level is changed to 0.5 μsec, 1.0 μsec, and 2.0 μsec. Then, as illustrated in FIG. 10, when the consumption current of the signal transmission circuit in the conventional art is compared with the consumption current of the signal transmission circuit 7 according to the present embodiment, since the configuration of the secondary side circuit 13 is the same, the current consumption on the secondary side is almost the same. On the contrary, in the signal transmission circuit 7, since the primary side circuit 12 generates the pulse based on the clock signal CLK, the consumption current is increased correspondingly. However, as illustrated in the figure, the cycle of the pulse signal output during the period when the input signal DIN is indicative of the high level is set to be longer, thereby being capable of reducing the consumption current on the primary side.

As described above, according to the present embodiment, the primary side circuit 12 forming the signal transmission circuit 7 generates the pulse signal for allowing the current to flow in the primary side coil L1 of the transformer 11 in one direction in the cycle shorter than the change cycle of the input signal during the period in which the input signal DIN is indicative of the high level. In addition, the primary side circuit 12 generates the pulse signal for allowing the current to flow in the primary side coil L1 in the direction opposite to the one direction in the cycle shorter than the change cycle of the input signal DIN during the period in which the input signal DIN is indicative of the low level, likewise. Then, the secondary side circuit 13 discriminates the high and low levels according to the voltage different in the polarity generated in the secondary side coil L2 of the transformer 11, to thereby reproduce the input signal.

With the configuration described above, even when the level is inverted due to an influence of noise during a period when the input signal DIN is indicative of the high or low level, a current based on the pulse signal having the cycle shorter than that generated by the primary side circuit 12 according to the binary level repetitively flows in the secondary side coil L2, and a voltage having a polarity corresponding to the current is generated. Since the secondary side circuit is 13 and reproduces the input signal DIN according to the polarity of the voltage, the inverted level of the input signal DIN is restored to the original level within a short time. For example, if the input signal DIN is a PWM signal with a duty of 50%, the input signal DIN can return to the original level within a time shorter than ½ of the carrier period at the latest. Accordingly, while an electric insulation between the primary side and the secondary side is performed with the use of the transformer 11, the influence caused by the level inversion is reduced, and a control using the input signal DIN can be restored to the original state more quickly.

Also, the primary side circuit 12 may change a period during which the pulse signal is generated between the period in which the input signal DIN is indicative of the high level and the period in which the input signal DIN is indicative of the low level. As a result, the cycle of the pulse signal to be generated for the high level at which the IGBT 2 turns on is set to be relatively shorter to return the input signal DIN to the original level immediately, and the cycle of the pulse signal to be generated for the low level at which the IGBT 2 turns off is set to be relatively longer, thereby being capable of reducing the power consumption.

The primary side circuit 12 includes the frequency divider 17 that divides the frequency of the clock signal CLK to output the clock signal CLK2, the AND gate 16 for outputting the clock signal CLK2 during the period in which the input signal DIN is indicative of the high level, the NOT gate 14 and the AND gate 15 for outputting the clock signal CLK during the period in which the input signal DIN is indicative of the low level, the H bridge circuit 20 whose respective output terminals are connected to both ends of the primary side coil L1, the pulse generation circuits 18(P1) and 19(N1) that output the pulse signals VP1 and VN1 to the FETs 21(P1) and 22(N1) in synchronization with the rising edge of the clock signal CLK2 output through the AND gate 16, respectively, and the pulse generation circuits 18(P2) and 19(N2) that output the pulse signals VP2 and VN2 to the FETs 21(P2) and 22(N2) in synchronization with the rising edge of the clock signal CLK2 output through the AND gate 15, respectively.

With the configuration described above, the output cycles of the pulse signals VP1 and VN1 can be changed according to a frequency division ratio set in the frequency divider 17, and when the IGBT2 that is in the on state is influenced by noise to turn off, a speed of a time for returning to the on state and a reduction amount of the power consumption can be adjusted.

Further, the secondary side circuit 13 includes the comparator 24R that generates the set signal VR when the voltage generated in the secondary side coil L2 is indicative of one polarity, the comparator 24F that generates the reset signal VF when the voltage is indicative of the other polarity, and the RS flip-flop 27 to which the set signal VR and the reset signal VF are input. With the configuration described above, the RS flip-flop 27 is set each time the primary side circuit 12 generates the pulse signals VP1 and VN1 to set the output signal DOUT to the high level, and reset each time the primary side circuit 12 generates the pulse signals VP2 and VN2 to set the output signal DOUT to the low level. Therefore, the secondary side circuit 13 can be simply configured.

In addition, the IGBT 2 forming the inverter circuit 1 is driven by the gate signal DOUT output from the signal transmission circuit 7. Accordingly, for example, in the case where the IGBT 2U is influenced by noise to turn on in a state where the IGBT 2U of an upper arm is turned off and the IGBT 2X of a lower arm is turned on, a situation in which a short-circuit current flows in the IGBTs 2U and 2X can be eliminated within a short time.

### Second Embodiment

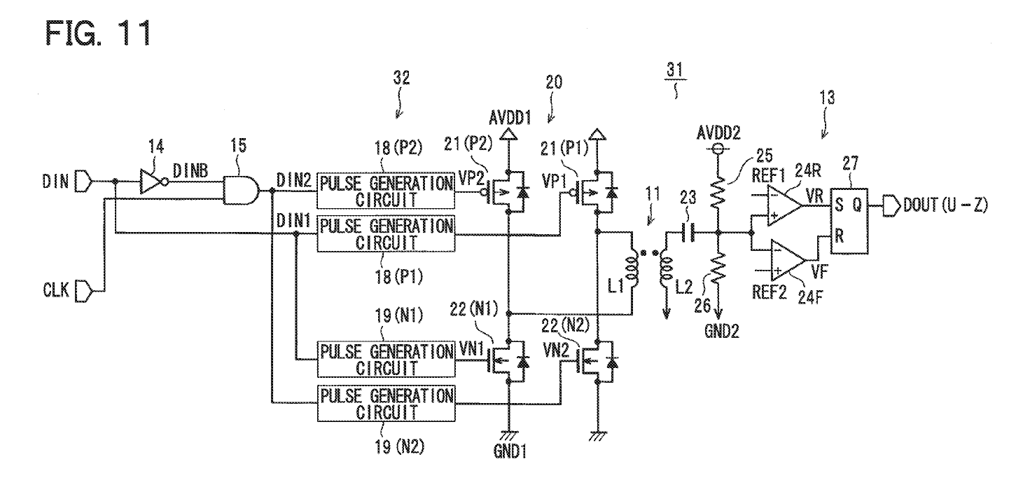

Hereinafter, the same reference signs will be assigned to the same portions as in the first embodiment. The same portions will not be described, and only different portions will be described. As illustrated in FIG. 11, a signal transmission circuit 31 according to the second embodiment is obtained by replacing the primary side circuit 12 with a primary side circuit 32, and the AND gate 16 and the frequency divider 17 are deleted from the configuration of the first embodiment. An input signal DIN is input directly to pulse generation circuits 18(P1) and 19(N1).

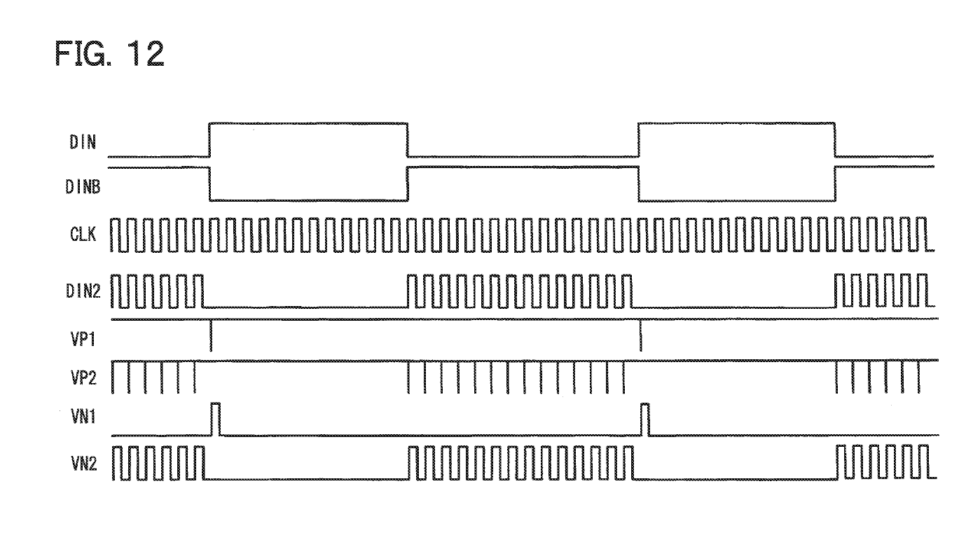

Hereinafter, the operation of the second embodiment will be described. As illustrated in FIG. 12, a low level pulse VP2 and a high level pulse VN2 output during a period in which the input signal DIN is indicative of the low level are the same as in the first embodiment.

On the other hand, the pulse generation circuits 18(P1) and 19(N1) output a low level pulse VP1 and a high level pulse VN1 with a rising edge of the input signal DIN as a trigger only once during a period when the input signal DIN is indicative of the high level. Therefore, when noise of an opposite polarity is applied within the above period, the output signal DOUT does not become the high level until the rising edge of the input signal DIN arrives next time similarly to the conventional art. As described above, according to the second embodiment, the effect of reducing the power consumption of the signal transmission circuit 31 is maximized without giving a returning effect during the noise application, with respect to the set signal VR side low in urgency of handling.

As described above, according to the second embodiment, the signal transmission circuit 31 eliminates the AND gate 16 and the frequency divider 17 from the configuration of the first embodiment, and replaces the primary side circuit 12 with the primary side circuit 32, and inputs the input signal DIN directly to the pulse generation circuits 18(P1) and 19(N1). As a result, the input signal DIN during the period in which the IGBT2 is on is not modulated by the primary side circuit 32, and when the signal level is reversed under the influence of noise within that period, the IGBT2 is turned off and the input signal DIN is not turned on until the input signal DIN is next indicative of the high level. Therefore, the effect of reducing the power consumption can be improved as compared with the first embodiment, and the same effects as those in the first embodiment can be obtained in the period during which the input signal DIN is indicative of the low level.

The present disclosure is not limited only to the embodiments described above or illustrated in the drawings, and the embodiments can be modified or expanded in the following manner.

One of the first and second levels may be set to the high level and the other may be set to the low level.

The change edge may be a falling edge.

A frequency division ratio in the frequency divider 17 may be “3” or more.

Further, in the first embodiment, the frequency divider 17 may be deleted.

The switching element that receives the drive signal through the signal transmission circuit is not limited to the IGBT, and may be configured by a MOSFET, a bipolar transistor, or the like.

If necessary, a pre-driver may be added to the signal transmission circuit to form a drive device.

The switching element driven by the output signal DOUT is not limited to the inverter circuit 1, but may be formed by a half bridge circuit or an H bridge circuit. Also, a single switching element may be driven.

The present disclosure is not limited to application to a drive device of the switching element, but can be applied to a device which needs to electrically insulate and transmit the input signal which changes at a binary level.

In the drawings, reference numeral 1 denotes an inverter circuit, 2 is an IGBT (switching element), 7 is a signal transmission circuit (drive device), 11 is a transformer, L1 is a primary side coil, L2 is a secondary side coil, 12 is a primary side circuit, 13 is a secondary side circuit, 14 is a NOT gate (second logic circuit), 15 is an AND gate (second logic circuit), 16 is an AND gate (first logic circuit), 17 is a frequency divider, 18(P1) and 19(N1) are pulse generation circuits (first on signal output circuits), 18(P2) and 19(N2) are pulse generation circuits (second on signal output circuits), 20 is an H bridge circuit, 21(P1) and 21(P2) are p-channel MOSFETs (switching elements), 22(N1) and 22(N2) are n-channel MOSFETs (switching elements), 24R is a comparator (set signal generation circuit), 24F is a comparator (reset signal generation circuit), and 27 is an RS flip-flop.

The above-mentioned disclosure includes the following embodiments.

According to the first aspect of the present disclosure, the signal transmission circuit includes a transformer, a primary side circuit that generates a pulse signal for allowing a current to flow in a primary side coil of the transformer in one direction during a period in which an input signal changing at a binary level is indicative of a first level in a cycle shorter than a change cycle of the input signal, and generates a pulse signal for allowing a current to flow in the primary side coil in a direction opposite to the one direction during a period in which the input signal is indicative of a second level in a cycle shorter than the change cycle of the input signal, and a secondary side circuit that discriminates the first and second levels according to a voltage different in polarity which is generated in a secondary side coil of the transformer to reproduce the input signal.

According to the signal transmission circuit described above, even when the level is inverted due to an influence of noise during a period when the input signal is indicative of the first or second level, a current based on the pulse signal having the cycle shorter than that generated by the primary side circuit according to the first or second level repetitively flows in the secondary side coil of the transformer, and a voltage having a polarity corresponding to the current is generated.

Since the secondary side circuit reproduces the input signal according to the polarity of the voltage, the inverted level is restored to the original first or second level within a short time. Accordingly, while an electric insulation between the primary side and the secondary side is performed with the use of the transformer, the influence caused by the level inversion due to the noise is reduced, and a control using the input signal can be restored to the original state more quickly.

Alternatively, the primary side circuit may change a period for generating the pulse signal between the period in which the input signal is indicative of the first level and the period in which the input signal is indicative of the second level.

For example, it is assumed that an on/off control of the switching element is performed with the use of the input signal reproduced by the secondary side circuit. In this case, the switching element is turned on in one of the binary levels indicated by the input signal, and turned off in the other level. In general, a case (1) in which the switching element in the on state is turned off under the influence of noise is more secure than a case (2) in which the switching element in the off state is turned on. For example, when two switching elements are connected in series with each other, there is a possibility that a short-circuit current flows in the case of (2).

Therefore, the cycle of the pulse signal generated for the level corresponding to the case (2) is set to be relatively short, thereby being capable of rapidly returning the input signal to the original level, and the cycle of the pulse signal generated for the level corresponding to the case (1) is set to be relatively long, thereby being capable of reducing the power consumption.

According to the second aspect of the present disclosure, the signal transmission circuit includes a transformer, a primary side circuit that generates a pulse signal for allowing a current to flow in a primary side coil of the transformer in one direction when an input signal changing at a binary level is indicative of a first level in a cycle shorter than a change cycle of the input signal, and generates a pulse signal for allowing a current to flow in the primary side coil in a direction opposite to the one direction during a period in which the input signal is indicative of a second level in a cycle shorter than the change cycle of the input signal, and a secondary side circuit that discriminates the first and second levels according to a voltage different in polarity which is generated in a secondary side coil to reproduce the input signal.

In the signal transmission circuit described above, the input signal can be transmitted in an insulated state with a small circuit scale while securing noise tolerance.

In this example, in the case where the above-described alternative is applied to the signal transmission circuit of the second aspect, the switching element is turned on at the first level, and the switching element is turned off at the second level. As a result, since the input signal during the period in which the switching element is on is not modulated by the primary side circuit, when the signal level is reversed under the influence of noise within that period, the switching element is turned off and the input signal is not turned on until the input signal is next indicative of the first level. When this state can be tolerated, the effect of reducing the power consumption can be obtained more than the above alternative. In the period during which the signal is indicative of the second level, the same effects as that of the above alternative can be obtained.

In a third aspect of the present disclosure, a drive device of a switching element includes the signal transmission circuit according to the first or second aspect. The input signal reproduced by the secondary side circuit of the signal transmission circuit drives and controls the switching element.

In the drive device of the switching element described above, the input signal can be transmitted in an insulated state with a small circuit scale while securing noise tolerance.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A signal transmission circuit comprising:
a transformer;
a primary side circuit that:
generates a pulse signal, for flowing a current in a primary side coil of the transformer in one direction during a period in which an input signal changing at a binary level indicates a first level, in a cycle shorter than a change cycle of the input signal; and
generates another pulse signal, for flowing a current in the primary side coil in another direction opposite to the one direction during a period in which the input signal indicates a second level, in another cycle shorter than the change cycle of the input signal; and
a secondary side circuit that:
distinguishes the first level and the second level according to a voltage having a different polarity which is generated in a secondary side coil of the transformer; and
reproduces the input signal, wherein:
the primary side circuit differentiates the cycle for generating the pulse signal during the period in which the input signal indicates the first level and the another cycle for generating the another pulse signal during the period in which the input signal indicates the second level.

2. (canceled)

3. The signal transmission circuit according to claim 1, wherein:
the primary side circuit includes:
an oscillation circuit that outputs a first clock signal having a cycle shorter than the change cycle of the input signal;
a frequency divider that divides a frequency of the first clock signal, and outputs a second clock signal;
a first logic circuit that performs a gate control to output one of the first clock signal and the second clock signal only for the period in which the input signal indicates the first level;
a second logic circuit that performs a gate control to output the other of the first clock signal and the second clock signal only for the period in which the input signal indicates the second level;
an H bridge circuit having a plurality of output terminals connected to both ends of the primary side coil respectively;
a first on-state signal output circuit that outputs a first on-state signal to a switching element providing the H bridge circuit to generate the pulse signal for flowing the current in the primary side coil in the one direction by the H bridge circuit in synchronization with one change edge of the clock signal output through the first logic circuit; and
a second on-state signal output circuit that outputs a second on-state signal to the switching element providing the H bridge circuit to generate the pulse signal for flowing the current in the primary side coil in the another direction opposite to the one direction by the H bridge circuit in synchronization with one change edge of the clock signal output through the second logic circuit.

4. A signal transmission circuit, comprising:
a transformer;
a primary side circuit that:
generates a pulse signal, for flowing a current in a primary side coil of the transformer in one direction when an input signal changing at a binary level indicates a first level, in a cycle shorter than a change cycle of the input signal; and
generates another pulse signal, for flowing a current in the primary side coil in another direction opposite to the one direction during a period in which the input signal indicates a second level, in another cycle shorter than the change cycle of the input signal; and
a secondary side circuit that:
distinguishes the first level and the second level according to a voltage having a different polarity which is generated in a secondary side coil of the transformer; and
reproduces the input signal, wherein:
the primary side circuit includes:
an oscillation circuit that outputs a clock signal having a cycle shorter than the change cycle of the input signal;
an inverted signal output circuit that outputs an inverted signal in which the level of the input signal is inverted;
a logic circuit that performs a gate control to output the clock signal only for the period in which the input signal indicates the second level;
an H bridge circuit having a plurality of output terminals connected to both ends of the primary side coil respectively;
a first on-state signal output circuit that outputs a first on-state signal to a switching element providing the H bridge circuit to generate the pulse signal for flowing the current in the primary side coil in the one direction by the H bridge circuit in synchronization with one change edge of the input signals; and
a second on signal output circuit that outputs a second on-state signal to the switching element providing the H bridge circuit to generate the pulse signal for flowing the current in the primary side coil in the another direction opposite to the one direction by the H bridge circuit in synchronization with one change edge of the clock signal output through the logic circuit.

5. (canceled)

6. The signal transmission circuit according to claim 1, wherein
the secondary side circuit includes:
a set signal generation circuit that generates a set signal when the voltage generated in the secondary side coil indicates one polarity;
a reset signal generation circuit that generates a reset signal when the voltage generated in the secondary side coil indicates the other polarity; and
an RS flip-flop to which the set signal and the reset signal are input.

7. A drive device of a switching element comprising:
the signal transmission circuit according to claim 1, wherein:
the driving device controls a drive of the switching element according to an input signal regenerated by the secondary side circuit of the signal transmission circuit.
